(19) United States
(12) Patent Application Publication
(10) Pub. No.: US 2005/0051877 A1
(43) Pub. Date: Mar. 10, 2005

(54) Semiconductor package having high quantity of I/O connections and method for fabricating the same

(75) Inventor: Chin-Teng Hsu, Taichung (TW)

Correspondence Address: Mr. Peter F. Corless;EDWARDS & ANGELL, LLP, 101 Federal Street, Boston, MA, 02110, US

(73) Assignee: Siliconware Precision Industries Co., Ltd.

(21) Appl. No.: 10/865,945

(22) Filed: Jun. 10, 2004

(30) Foreign Application Priority Data
Sep. 10, 2003 (TW) 092124968

(51) Int. Cl. H01L 23/48

(52) U.S. Cl. 257/667

(57) ABSTRACT

A semiconductor package having a high quantity of input/output (I/O) connections and a fabrication method thereof are proposed. A lead frame having a plurality of leads, a die pad and at least one conductive member electrically isolated from the die pad and disposed between the die pad and leads, is provided for at least one semiconductor chip to be mounted on the die pad. The semiconductor chip is electrically connected to the leads and the at least one conductive member. An encapsulant is formed to encapsulate the semiconductor chip and a portion of the lead frame with bottom surfaces of the die pad and the at least one conductive member and a portion of the leads being exposed from the encapsulant. The at least one conductive member electrically separated from the die pad is used as an I/O connection for external connection between the semiconductor chip and external devices.

### FIELD OF THE INVENTION

The present invention relates to semiconductor packages, and more particularly to a semiconductor package having a lead frame as a chip carrier and a method for fabricating the same.

### BACKGROUND OF THE INVENTION

A conventional semiconductor package having a lead frame as a chip carrier is typically provided with a semiconductor chip mounted on a die pad of the lead frame, wherein leads of the lead frame are disposed around the die pad and have outer leads exposed from an encapsulant or mold body that is used for encapsulating the chip and the lead frame, the exposed outer leads serving as input/output (I/O) connections for electrical connection between the semiconductor package and external devices. This type of semiconductor package device is customarily named Quad Flat Package (QFP), which has been developed with various modified configurations as disclosed in U.S. Pat. Nos. 5,397,746, 5,905,299, 5,559,306, 5,923,092 and 5,489,801.

According to the above cited U.S. patents, as shown in FIGS. 12 and 13, leads 10′ of a conventional QFP device 1′ have outer leads 100′ exposed and extended to outside of an encapsulant 11′. The number of leads 10′ (i.e. the number of I/O connections) that can be provided in the QFP device 1′ is restricted by two factors: a pitch between any two adjacent leads and the length of a side S′ of the encapsulant 11′, as shown in FIG. 13. For example, a 28 mm×28 mm QFP device with a pitch of 0.5 mm between adjacent leads can accommodate 52 leads on a single side of the encapsulant; that is, 208 leads in total can be provided in such a QFP device and serve as I/O connections for electrical connection with external devices.

Therefore, in the case of the encapsulant remaining constant in size, the only way to increase the number of leads is to reduce the pitch between adjacent leads. However, reducing the pitch between adjacent leads requires tremendous precision in manufacturing the lead frame and thus undesirably increases the fabrication cost. Further, when the leads with the reduced pitch are attached to an external device such as printed circuit board (PCB) by surface mounting technique (SMT), short circuit may be easily induced due to the reduced pitch, thereby degrading the yield on the electrical connection with the external device. On the contrary, if not to reduce the pitch between adjacent leads to avoid the foregoing drawback, an alternative is to increase the size of the encapsulant so as to accommodate more leads. However, the increase in size of the encapsulant not only increases the fabrication cost but also easily leads to warpage of the encapsulant, which adversely affects the yield of the fabricated packages. Further, the encapsulant with the increased size does not comply with current demands for light-weight and low-profile semiconductor packages.

Therefore, it is greatly desired to develop a semiconductor package with an increased number of I/O connections without increasing the size of the encapsulant and without reducing the pitch between adjacent leads.

Accordingly, U.S. Pat. No. 6,348,726 discloses a semiconductor package with a leadless lead frame as a chip carrier. As shown in FIG. 15, the lead frame 10″ used in this semiconductor package 1″ comprises a die pad 100″, a plurality of conductive pads 101″ disposed around the die pad 100″, and a plurality of tie bars 102″ for connecting the conductive pads 101″ together. The lead frame 10″ is connected to a peripheral frame 11″ by a plurality of corner-situated support bars 103″. As shown in FIG. 14, a semiconductor chip 12″ is mounted on the die pad 100″ and electrically connected to the conductive pads 101″ via a plurality of gold wires 13. An encapsulant 14″ is formed to encapsulate the chip 12″, the gold wires 13″ and the lead frame 10″, allowing bottom surfaces 101a″ of the conductive pads 101″ to be exposed from the encapsulant 14″. A cutting process is performed cut off the tie bars 102″ between the adjacent conductive pads 101″ thereby forming a plurality of cut grooves 15″ that are parallel or vertical to each other. As a result, the conductive pads 101″ are electrically isolated from each other and can serve as I/O connections for electrical connection between the chip 12″ and external devices.

Although the above semiconductor package 1″ may have more I/O connections, fabrication of the lead frame 10″ shown in FIG. 15 is complex and cost-ineffective. Further, the lead frame 10″ is connected to the peripheral frame 11″ merely using the support bars 103″ provided at the four corners, and the lead frame 10″ is relatively thin, it is usually difficult to maintain the conductive pads 101″ at the outermost and the innermost positions coplanar during a wire-bonding process, thereby resulting in undesirable warpage of the lead frame 10″ and unsatisfactory bonding quality between the outer conductive pads 101″ and the chip 12″ thereon. As a result, the yield and reliability of the fabricated packages would be reduced. This problem becomes even more severe in the case of increasing the size of the lead frame for carrying more conductive pads. Moreover, due to the small size of the conductive pads 101″, it is not applicable to use a jig that is for clamping the outer leads of the conventional lead frame to prevent the occurrence of warpage, and therefore the quality of wire bonding for the lead frame 10″ cannot be assured. In addition, as mentioned above that the lead frame 10″ is complex and cost-ineffective to fabricate, thus there still remains a need to improve such a semiconductor package 1″.

### SUMMARY OF THE INVENTION

A primary objective of the present invention is to provide a semiconductor package having a high quantity of input/output (I/O) connections and a method of fabricating the same, without having to increase the size of an encapsulant or reducing a pitch between adjacent leads to provide a relatively high quantity of I/O connections with low fabrication cost as well as eliminating warpage or other electrical connection problems when the semiconductor package is connected to external devices.

In order to achieve the foregoing and other objectives, the invention proposes a semiconductor package having a high quantity of I/O connections, comprising: a lead frame having a plurality of leads, a die pad having a bottom surface, and at least one conductive member electrically isolated from the die pad so as for the conductive member to be disposed between the leads and the die pad, wherein the conductive member has a bottom surface; at least one semiconductor chip mounted on the die pad and respectively electrically connected to the leads and the conductive member; and an encapsulant for encapsulating the semiconductor chip and a portion of the lead frame, allowing a portion of the leads and the bottom surfaces of the conductive member and the die pad to be exposed from the encapsulant, such that the conductive member and the leads serve as I/O connections for electrical connection between the semiconductor chip and external devices.

The exposed portion of the leads from the encapsulant is referred to as outer leads in a Quad Flat Package (QFP) device, and comprises bottom surfaces of the leads in Quad Flat Non-leaded (QFN) device.

The at least one conductive member disposed between the die pad and the leads is located in a free space between the die pad and inner ends of the leads in a lead-frame-based semiconductor package, thereby no need to increase the size of the lead frame for accommodating the conductive member. That is, any conventional lead frame with a standard size can be used to form the conductive member.

The at least one conductive member may be a signal I/O member for being connected to a single bonding wire, or a ground ring and/or power ring for accommodating a plurality of bonding wires. The conductive member is flexibly shaped such as strip- or L-shape according to the practical requirement.

A method for fabricating the semiconductor package having a high quantity of I/O connections in the present invention comprises the steps of: preparing a lead frame having a plurality of leads, a die pad having a bottom surface, at least one conductive member connected to the die pad and disposed between the leads and the die pad wherein the conductive member having a bottom surface, and at least one connection portion for connecting the conductive member to the die pad; mounting at least one semiconductor chip on the die pad of the lead frame, and electrically connecting the semiconductor chip respectively to the leads and the conductive member; forming an encapsulant to encapsulate the semiconductor chip and a portion of the lead frame, allowing the bottom surface of the die pad, the bottom surface of the conductive member, the connection portion, and a portion of the leads to be exposed from the encapsulant; and removing the connection portion to electrically isolate the conductive member from the die pad, such that the conductive member and the leads serve as I/O connections for electrical connection between the semiconductor chip and external devices.

The at least one connection portion can be removed using a conventional mechanical sawing or grinding technique. When the connection portion is removed by the mechanical sawing process, the thickness of the connection portion is approximately the same as the thicknesses of the die pad or leads and the conductive member, or can be smaller than the thicknesses of the die pad or leads and the conductive member through the use of a stamping or etching process to reduce the thickness of the connection portion. In other words, in order to completely remove the connection portion, the sawing depth must be at least equal to the thickness of the connection portion. The removal process is easier to implement in the case of the thickness of the connection portion smaller than the thicknesses of the die pad or leads and the conductive member. Alternatively, when the connection portion is removed using a grinding technique, the die pad, the connection portion, the conductive member, the encapsulant and the leads of a QFN package are simultaneously ground. In this case, the thickness of the connection portion must be smaller than that of the die pad, such that after the grinding depth reaches the thickness of the connection portion, the connection portion can be completely removed, making the conductive member electrically isolated from the die pad. Further, since the die pad, the conductive member, the encapsulant, and the leads of the QFN package are ground and thinned, the overall thickness of the fabricated semiconductor package is also reduced making the package profile further miniaturized.

The removal of the connection portion can be also achieved through laser sawing or chemical etching.

The at least one conductive member is integrally connected to a side of the die pad. One advantage by this arrangement is that, during a wire-bonding process, the bottom surface of the die pad is sucked by a vacuum socket, allowing the conductive member along with the die pad to be firmly attached to a jig and thereby preventing the conductive member from warpage, such that the quality of wire bonding can be assured. On the contrary, if the conductive member is formed on an inner end of a lead, it increases the length of the lead, and during the wire-bonding process, the inner end of the lead having the conductive member cannot well clamped by the jig and would be subject to warpage, thereby degrading the quality of wire bonding. Therefore, formation of the conductive member on the inner end of the lead is not applicable.

### BRIEF DESCRIPTION OF THE DRAWINGS

The present invention can be more fully understood by reading the following detailed description of the preferred embodiments, with reference made to the accompanying drawings, wherein:

FIG. 1A is a bottom view of a semiconductor package according to a first preferred embodiment of the present invention;

FIG. 1B is a cross-sectional view of the semiconductor package in FIG. 1A taken along line 1B-1B;

FIG. 1C is a schematic diagram showing the semiconductor package in FIG. 1B being electrically connected to a printed circuit board;

FIGS. 2A to 2E are schematic diagrams showing the procedural steps of a method for fabricating the semiconductor package according to the first preferred embodiment of the present invention;

FIG. 3 is a cross-sectional view of a semiconductor package according to a second preferred embodiment of the present invention;

FIGS. 4A to 4E are schematic diagrams showing the procedural steps of a method for fabricating the semiconductor package according to the second preferred embodiment of the present invention;

FIG. 5 is a cross-sectional view of a semiconductor package according to a third preferred embodiment of the present invention;

FIG. 6 is a schematic diagram showing the semiconductor package during a grinding process according to the third preferred embodiment of the present invention;

FIG. 7 is a cross-sectional view of a semiconductor package according to a fourth preferred embodiment of the present invention;

FIGS. 8A to 8E are schematic diagrams showing the procedural steps of a method for fabricating the semiconductor package of the fourth preferred embodiment of the present invention;

FIG. 9 is a cross-sectional view of a semiconductor package according to a fifth preferred embodiment of the present invention;

FIG. 10 is a bottom view of a semiconductor package according to a sixth preferred embodiment of the present invention;

FIG. 11 is a bottom view of a semiconductor package according to a seventh preferred embodiment of the present invention;

FIG. 12 (PRIOR ART) is a cross-sectional view of a conventional QFP device;

FIG. 13 (PRIOR ART) is a bottom view of the conventional QFP device in FIG. 12;

FIG. 14 (PRIOR ART) is a cross-sectional view of a semiconductor package disclosed in U.S. Pat. No. 6,348,726; and

FIG. 15 (PRIOR ART) is a bottom view of a lead frame shown in the semiconductor package of FIG. 14.

### DETAILED DESCRIPTION OF THE PREFERRED EMBODIMENTS

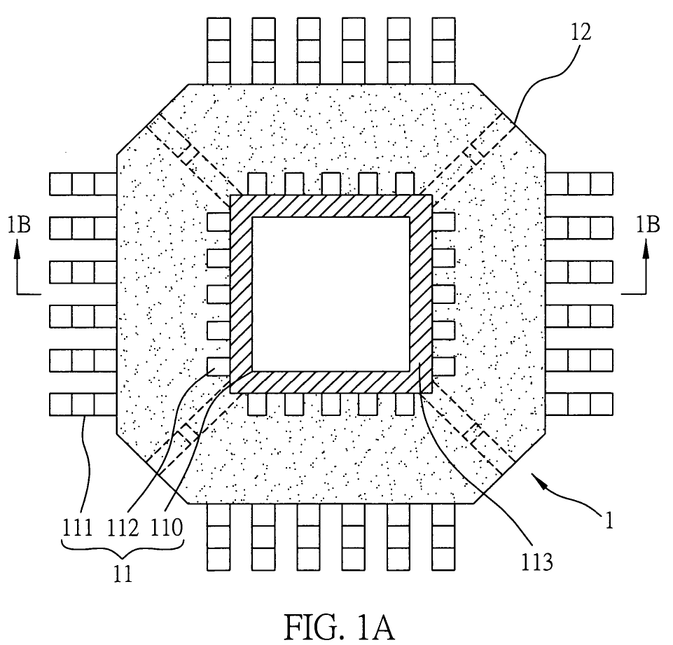

FIG. 1A shows a bottom view of a semiconductor package having a high quantity of I/O connections in accordance with a first preferred embodiment of the present invention, and FIG. 1B is a cross-sectional view of the semiconductor package in FIG. 1A taken along line 1B-1B.

As shown in the drawings, the semiconductor package 1 comprises a semiconductor chip 10, a lead frame 11 for carrying the chip 10, and an encapsulant 12 for encapsulating the chip 10 and a portion of the lead frame 11.

The lead frame 11 comprises a die pad 110, a plurality of leads 111 disposed around the die pad 110, and a plurality of conductive members 112 formed between the die pad 110 and the leads 11, as shown in FIG. 1B. The die pad 110 has a top surface 110a, and a bottom surface 110b opposed to the top surface 110a, wherein the bottom surface 110b is exposed from the encapsulant 12. Similarly, each of the conductive members 112 has a top surface 112a, and a bottom surface 112b opposed to the top surface 112a and exposed from the encapsulant 12. It should be noted that the conductive members 112 are separated and electrically isolated from the die pad 110 and the leads 11. Moreover, in order to expose the bottom surface 110b of the die pad 110 and the bottom surfaces 112b of the conductive members 112 from the encapsulant 12, there is a downset or height difference formed between the leads 111 and the die pad 110 and between the leads 111 and the conductive members 112, as shown in FIG. 1B.

The semiconductor chip 10 is attached to the top surface 110a of the die pad 110 via a conventional adhesive 13 such as silver paste. Then, the chip 10 is electrically connected to the leads 111 by a plurality of first bonding wires such as gold wires 14a, and electrically connected to the top surfaces 112a of the conductive members 112 by a plurality of second gold wires 14b. Since the chip 10 is respectively electrically connected to the leads 111 and the conductive members 112, the leads 111 each having an outer portion exposed from the encapsulant 12 and the conductive members 112 both serve as I/O connections for electrically connecting the semiconductor package 1 to external devices. Referring to FIG. 1C, the leads 111 and the conductive members 112 can be electrically connected to a printed circuit board P via solder paste S. Besides the leads 111, the conductive members 112 provide additional I/O connections for the semiconductor package 1 for the electrical connection with the printed circuit board P. Therefore, as compared to a conventional semiconductor package having the same pitch and the same size, the semiconductor package in the present invention provided with more I/O connections is suitable for use with a more advanced semiconductor chip.

Since the conductive members 112 are formed in a gap between the die pad 110 and the leads 111, there is no need to increase the size of the lead frame 11 to accommodate the conductive members 112. In other words, with a pitch between any two adjacent leads 111 and the overall size of the lead frame 11 remaining constant, it is allowed to form the conductive members 112 acting as additional I/O connections or signal I/O members for the semiconductor package according to the present invention. Further since the lead frame used in the present invention has the same size as the conventional lead frame, the current packaging equipment can be used to manufacture the semiconductor package in the present invention thereby reducing the fabrication cost.

Further referring to FIGS. 1A and 1B, there is a recess 113 formed between the conductive members 112 and the die pad 110 to separate and electrically isolate the conductive members 112 from the die pad 110. The depth of the recess 113 is the same as the thicknesses of the conductive members 112 and the die pad 110. The fabrication and function of the recess 113 are detailed in a fabrication method below.

Moreover, the die pad 110 with its bottom surface 110b exposed from the encapsulant 12 provides a relatively shorter heat dissipating path for the chip 10 mounted on the die pad 110. That is, heat generated from the chip 10 is transmitted to the die pad 110 and dissipated from the exposed bottom surface 110b of the die pad 110 to the external devices (such as PCB). Furthermore, in order to avoid delamination between the chip 10 and the die pad 110 induced by an excessive contact area therebetween due to mismatch in coefficient of thermal expansion (CTE) during a temperature cycle, at least one opening (not shown) can be formed through the die pad 110 to reduce the contact area between the chip 10 and the die pad 110 and thereby reduce the thermal stress exerted from the die pad 110 on the chip 10.

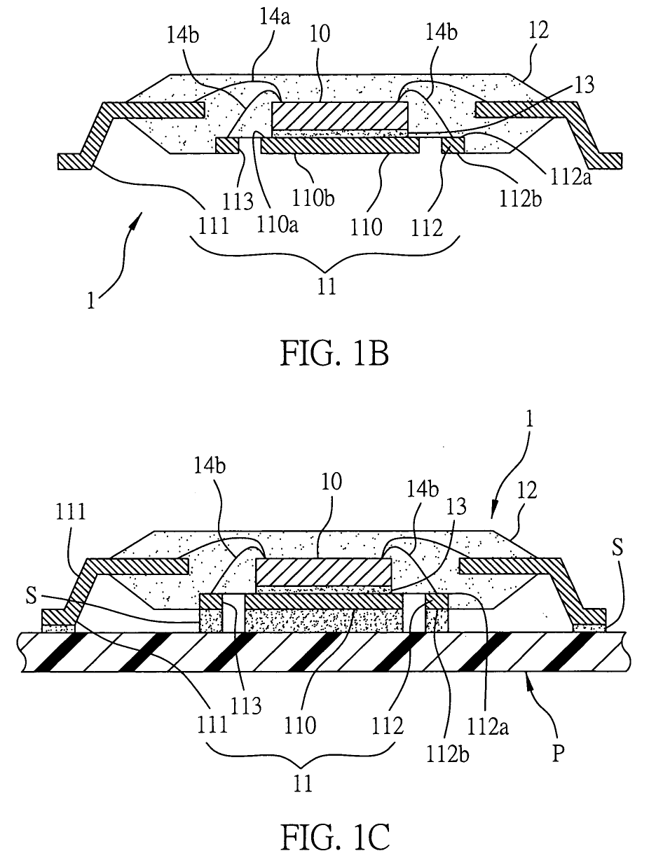

The procedural steps of a method for fabricating the above semiconductor package according to the first preferred embodiment of the present invention are described with reference to FIGS. 2A to 2E.

Referring to FIG. 2A, a lead frame 11 made of copper or an alloy thereof is prepared. The lead frame 11 comprises a die pad 110, a plurality of leads 111, a plurality of conductive members 112, and a plurality of connection portions 114 for integrally connecting the conductive members 112 to the die pad 110. In particular, the conductive members 112 are extended from sides of the die pad 110 and spaced apart from each other.

Referring to FIG. 2B, a semiconductor chip 10 is attached to a top surface 110a of the die pad 110 via an adhesive 13. Alternatively, more than two semiconductor chips having the same or different functions can be mounted on the die pad in a stacking manner according to the practical requirement.

Then, referring to FIG. 2C, a set of gold wires 14a are bonded between the chip 10 and the leads 111 to electrically connect the chip 10 to the leads 111. Also another set of gold wires 14b are bonded between the chip 10 and top surfaces 112a of the conductive members 112 to electrically connect the chip 10 to the conductive members 112.

Referring to FIG. 2D, after completing the above wire-bonding process, a molding process is performed to form an encapsulant 12 for encapsulating the chip 10, gold wires 14a, 14b and a portion of the lead frame 11. When the encapsulant 12 is fabricated, a bottom surface 110b of the die pad 110, bottom surfaces 112b of the conductive members 112, bottom surfaces 114b of the connection portions 114, and a portion of the leads 111 are exposed from the encapsulant 12.

The foregoing die-bonding, wire-bonding and molding processes are all well known in the art and thus not to further detailed here.

Then, referring to FIG. 2E, the connection portions 114 are removed using a conventional laser sawing technique as indicated by the arrows, and a recess 13 is formed after the connection portions 114 are completely removed. As a result, the conductive members 112 are completely electrically isolated from the die pad 110 via the recess 13 to form a structure as shown in the semiconductor package 1 of FIG. 1B according to the first preferred embodiment of the present invention. It should be noted that in order to completely remove the connection portions 114 and completely isolate the conductive members 112 from the die pad 110, the cutting depth must at least be equal to the thickness of the connection portions 114 so as to prevent incomplete removal of the connection portions 114 between the conductive members 112 and the die pad 110.

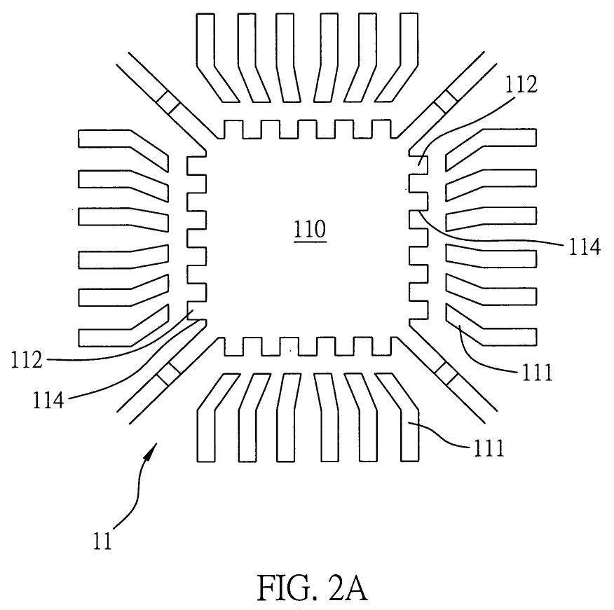

FIG. 3 shows a semiconductor package 2 according to a second preferred embodiment of the present invention. As shown, this semiconductor package 2 is mostly the same in structure as that of the first preferred embodiment, except that in the semiconductor package 2, the depth of the recess 213 between the conductive members 212 and the die pad 210 is approximately half of the thicknesses of the conductive members 212 and the die pad 210. Fabrication of the recess 213 is described in detail hereafter.

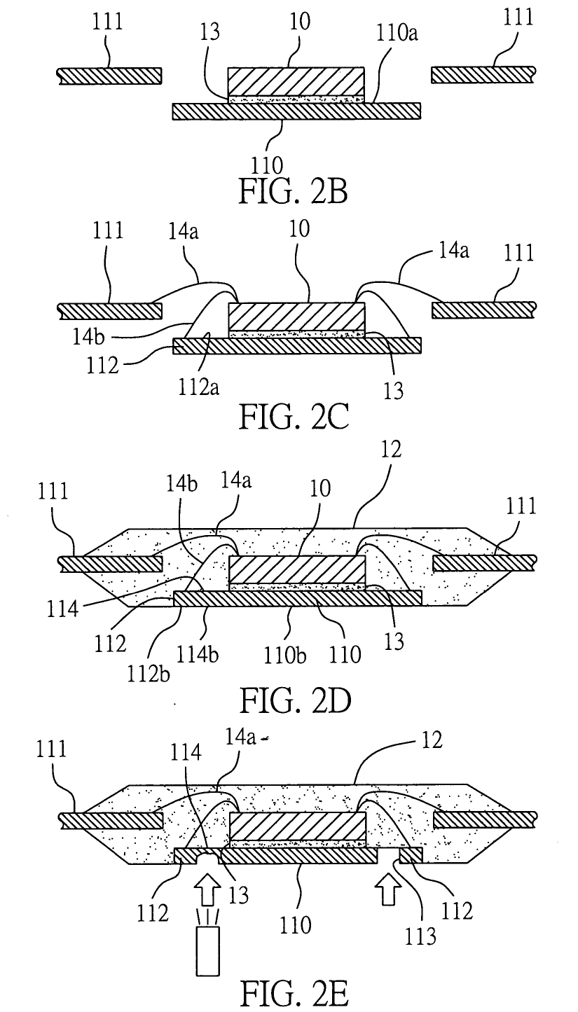

The procedural steps of a method for fabricating the above semiconductor package according to the second preferred embodiment of the present invention are described with reference to FIGS. 4A to 4E.

Referring to FIG. 4A, a lead frame 21 is prepared comprising a die pad 210, a plurality of leads 211 disposed around the die pad 210, a plurality of conductive members 212 formed between the die pad 210 and the leads 211, and a plurality of connection portions 214 for integrally connecting the conductive members 212 to the die pad 210. The thickness of the connection portions 214 is only half of the thicknesses of the die pad 210 and the leads 211, and this halved thickness is achieved using a conventional etching or stamping technique to form recesses at the connection portions 214.

Then, referring to FIGS. 4B to 4D, a semiconductor chip 20 is mounted on the die pad 210 and electrically connected to the leads 211 and the conductive members 212 by bonding wires 24a, 24b respectively. Subsequently, a molding process is performed to form an encapsulant 22. The wire-bonding and molding processes are similar to those described in FIGS. 2B to 2D, thus not to be further detailed here.

Finally referring to FIG. 4E, a conventional laser or sawing technique is employed to remove the connection portions 214 as indicated by the arrows. After the connection portions 214 are completely removed, a recess 213 as shown in FIG. 3 is formed such that the conductive members 212 are completely electrically isolated from the die pad 210. Since the thickness of the connection portions 214 is smaller than those of the conductive members 212 and the die pad 210, removal of the connection portions 214 can be performed more quickly than that of the connection portions 114 in the above first preferred embodiment.

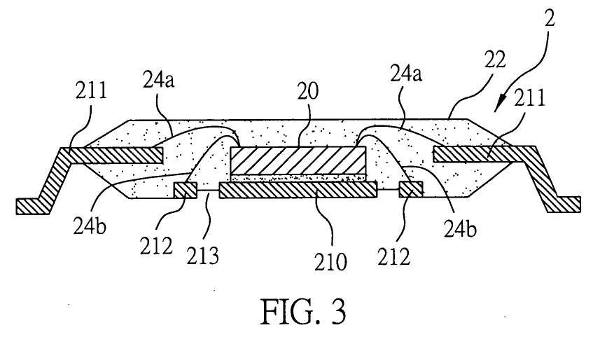

FIG. 5 shows a semiconductor package 3 according to a third preferred embodiment of the present invention. This semiconductor package 3 is mostly the same in structure as that of the second preferred embodiment, except that in the semiconductor package 3, the connection portions 314 of the semiconductor package 3 are removed using a grinding technique, such that no recess is formed between the die pad 310 and the conductive members 312 after the removal process, and the conductive members 312 are electrically isolated from the die pad 310 by means of the encapsulant 32 formed for encapsulating the semiconductor chip 30 and a portion of the lead frame.

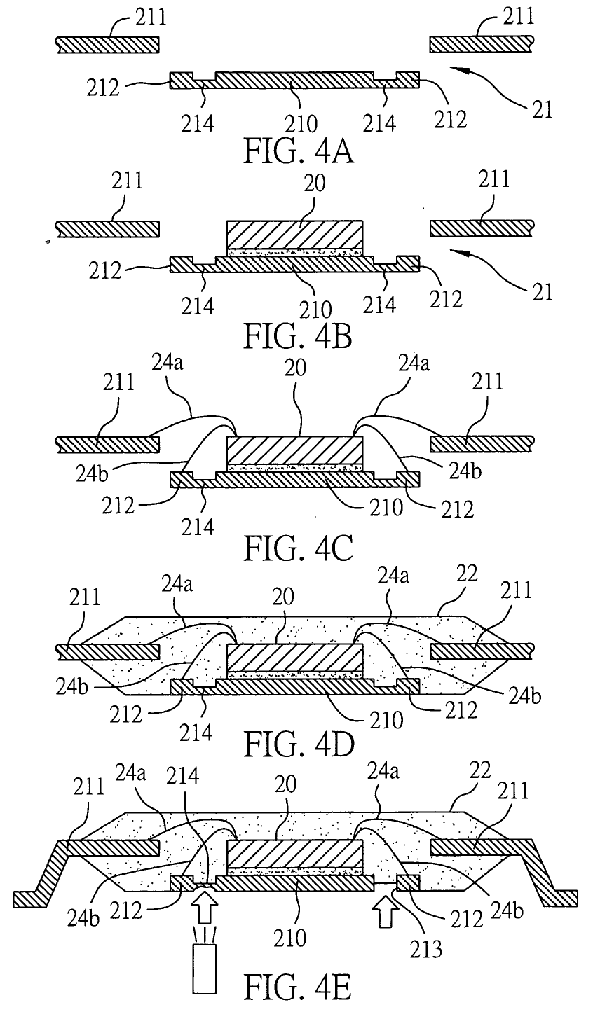

The fabrication processes for the semiconductor package 3 up to completion of the molding process for forming the encapsulant 32 are the same as those for the semiconductor package 2 in the second preferred embodiment, thereby not to be further detailed here. FIG. 6 only shows the different fabrication processes for the semiconductor package 3 as compared to the second preferred embodiment.

As shown in FIG. 6, when the encapsulant 32 is formed, bottom surfaces of the die pad 310, the conductive members 312 and the connection portion 314 are all exposed from the encapsulant 32. In this embodiment, a grinding process using any suitable conventional grinding machine G is performed to grind a bottom surface 32b of the encapsulant 32 so as to remove a portion of the encapsulant 32, a portion of the die pad 310, a portion of the conductive members 312, and the connection portions 314. When the grinding depth reaches the thickness of the connection portions 314, the connection portions 314 are completely removed by the grinding machine G, making the conductive members 312 separated and electrically isolated from the die pad 310. Moreover, half of the thicknesses of the die pad 310 and the conductive members 312 is ground off, and a corresponding thickness of the encapsulant 32 is also removed, thereby forming the semiconductor package 3 in FIG. 5 thinner than that shown in FIG. 6 before the grinding process. The fabricated semiconductor package 3 with the reduced thickness further complies with the requirement of miniaturization in package size.

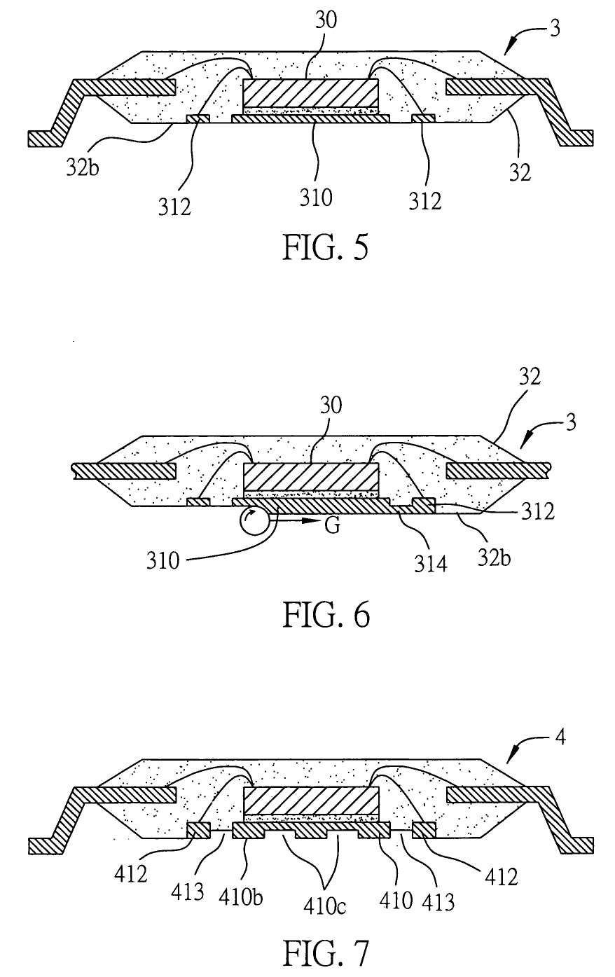

FIG. 7 shows a semiconductor package 4 according to a fourth preferred embodiment of the present invention.

As shown in FIG. 7, this semiconductor package 4 is mostly the same in structure as that of the second preferred embodiment. However, the semiconductor package 4 further comprises a plurality of recesses 410c formed on a bottom surface 410b of the die pad 410 and having the same depth as the recess 413 disposed between the die pad 410 and the conductive members 412. Formation of the recesses 410c is described in the following fabrication method.

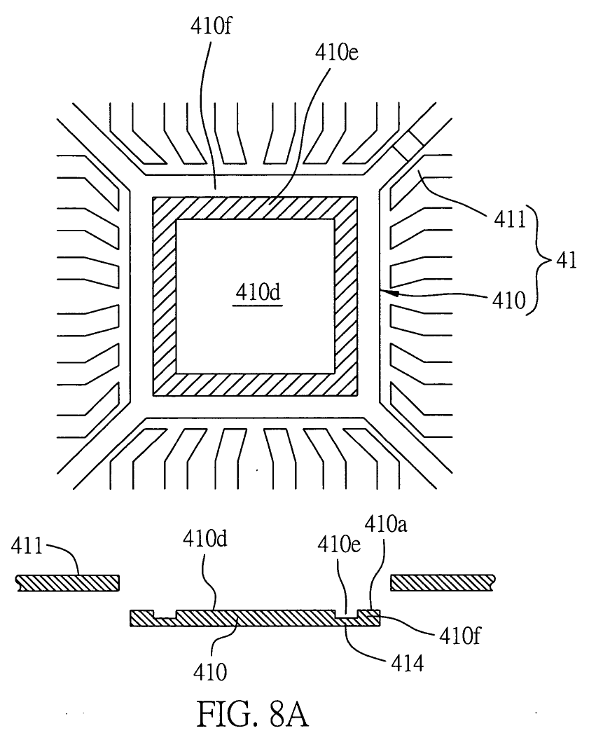

FIGS. 8A to 8E shows the procedural processes of a method for fabricating the semiconductor package 4 according to the fourth preferred embodiment of the present invention, which are similar to those for the foregoing second preferred embodiment.

Referring to FIG. 8A, first, a lead frame 41 having a die pad 410 and a plurality of leads 411 disposed around the die pad 410 is prepared. A chip bonding region 410d is defined on a top surface 410a of the die pad 410, and a recess 410e is formed around the chip bonding region 410d. The thinned part of the die pad 410 beneath the recess 410e forms a connection portion 414, and a portion of the die pad 410 located around the connection portion 414 is referred to as a conductive member region 410f. The depth and width of the recess 410e are not particularly limited but are determined according to the practical requirement. In this embodiment, the depth of the recess 410e or the thickness of the corresponding connection portion 414 is preferably half of the thickness of the die pad 410.

Then referring to FIG. 8B, a semiconductor chip 40 is mounted on the chip bonding region 410d of the die pad 410 via a conventional adhesive 43.

Referring to FIG. 8C, a set of gold wires 44a are provided to electrically connect the chip 40 to the leads 411, and another set of gold wires 44b are formed to electrically connect the chip 40 to the conductive member region 410f of the die pad 410, such that the chip 40 is respectively electrically connected to the leads 411 and the conductive member region 410f via the gold wires 44a, 44b.

Referring to FIG. 8D, a molding process is carried out to form an encapsulant 42 for encapsulating the chip 40 and a portion of the lead frame 41, allowing a bottom surface of the die pad 410 to be exposed from the encapsulant 42.

Referring to FIG. 8E, a conventional sawing technique is adopted to cut the connection portion 414, the die pad 410 and the encapsulant 42 in an alternate crisscross manner so as to completely remove the connection portion 414. As a result, the conductive member region 410f is divided into a plurality of conductive members 412 that are electrically isolated from the chip bonding region 410d of the die pad 410, and a plurality of interlaced recesses 413 is formed on a bottom surface 42b of the encapsulant 42. This thus completes the fabrication processes for the semiconductor package 4 shown in FIG. 7.

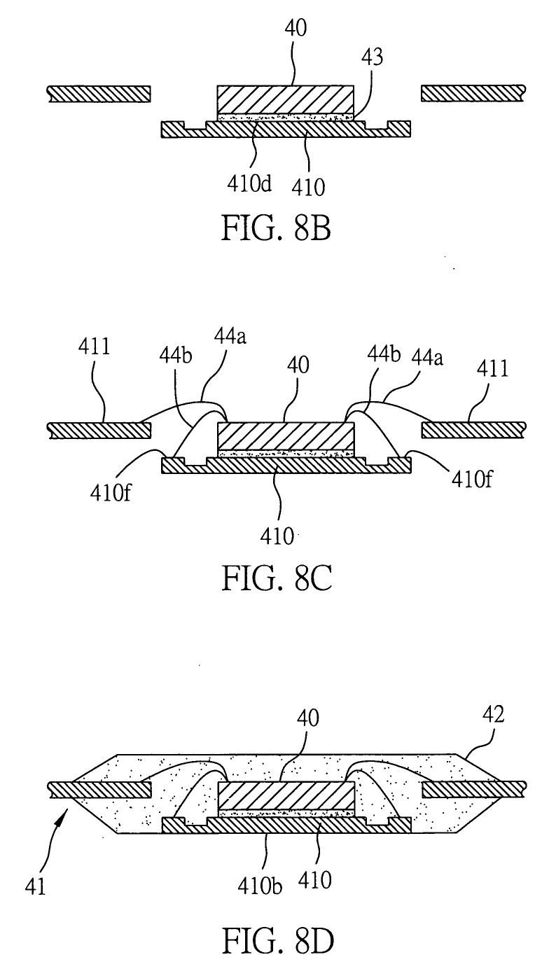

Referring to FIG. 9, it shows a semiconductor package 5 according to a fifth preferred embodiment of the present invention. This semiconductor package 5 is mostly the same in structure as that of the first preferred embodiment, except that in the semiconductor package 5, there is no downset or height different between the leads 511 and the die pad 510, and thus after the encapsulant 52 is formed, bottom surfaces of the leads, the die pad 510 and the conductive members 512 are all exposed from the encapsulant 52. That is, the semiconductor package 5 is a QFN package structure. Since the die pad 510 and the leads 511 are coplanar, after the encapsulant 52 is formed, a mechanical sawing or laser technique can be used to remove a connection part between the conductive members 512 and the die pad 510, allowing the conductive members 512 to be electrically isolated from the die pad 510, and forming a recess 513 between the die pad 510 and the conductive members 512.

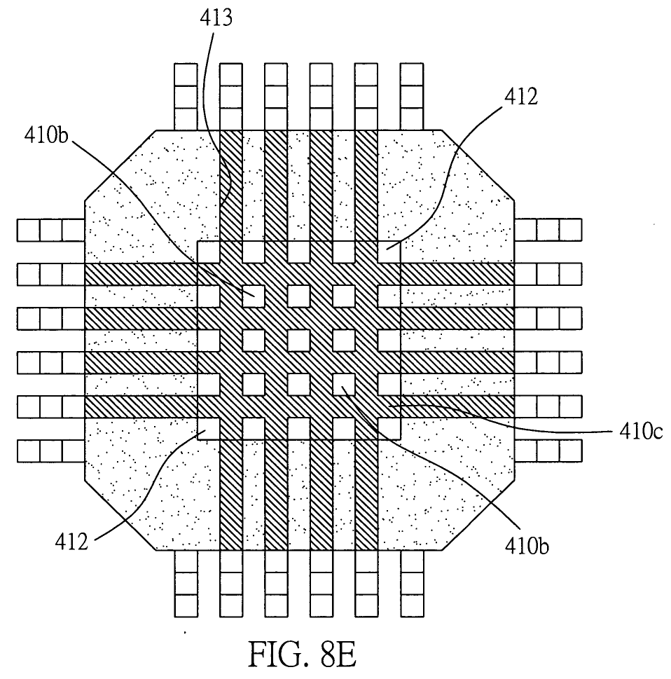

FIG. 10 shows a semiconductor package 6 according to a sixth preferred embodiment of the present invention. This semiconductor package 6 is mostly the same in structure as that of the foregoing first preferred embodiment, except that in the semiconductor package 6, the conductive members 612 formed between the leads 611 and the die pad 610 have a dual-layer arrangement, and recesses 613 are respectively formed between the two layers of the conductive members 612 and between the conductive members 612 and the die pad 610. This increased number of conductive members 612 provides more I/O connections for the semiconductor chip 60 mounted on the die pad 610. It is understood that the conductive members can be arranged in multiple layers (more than two layers) to provide an even higher number of I/O connections according to the requirement for the semiconductor chip. This technology is well known in the art, thus not to be further detailed here.

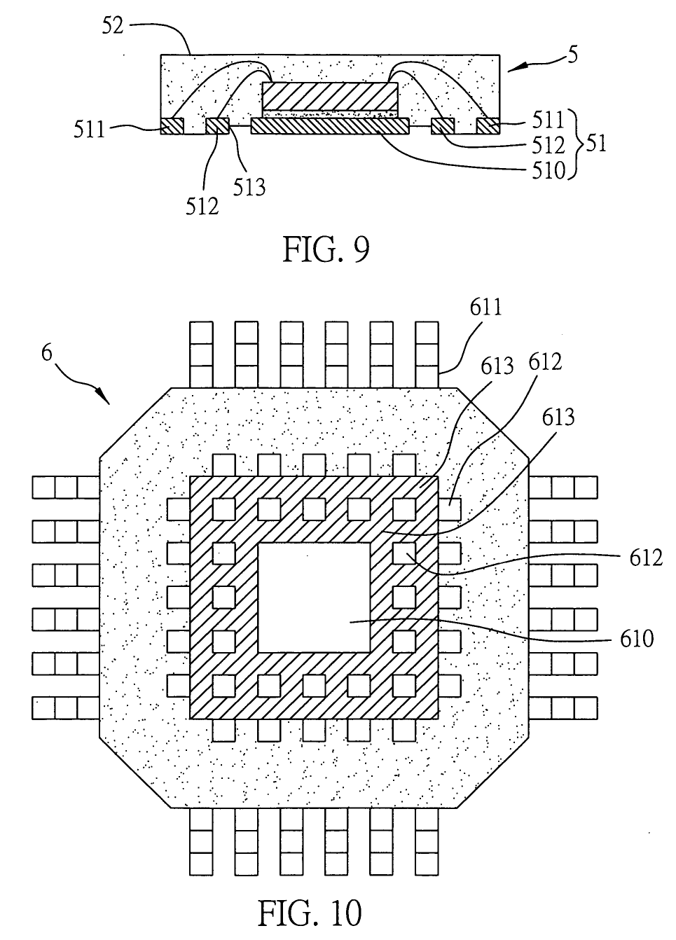

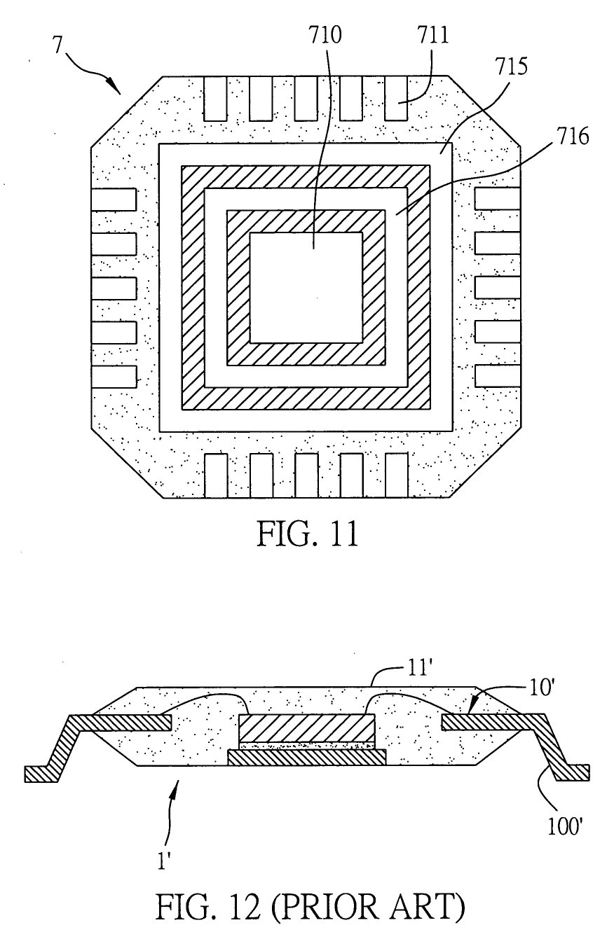

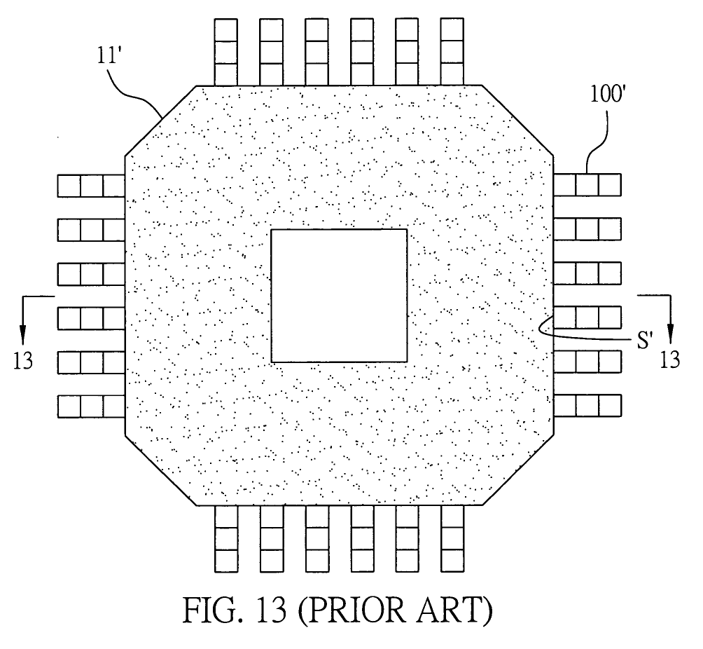

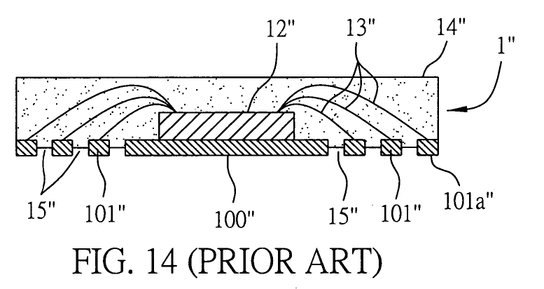

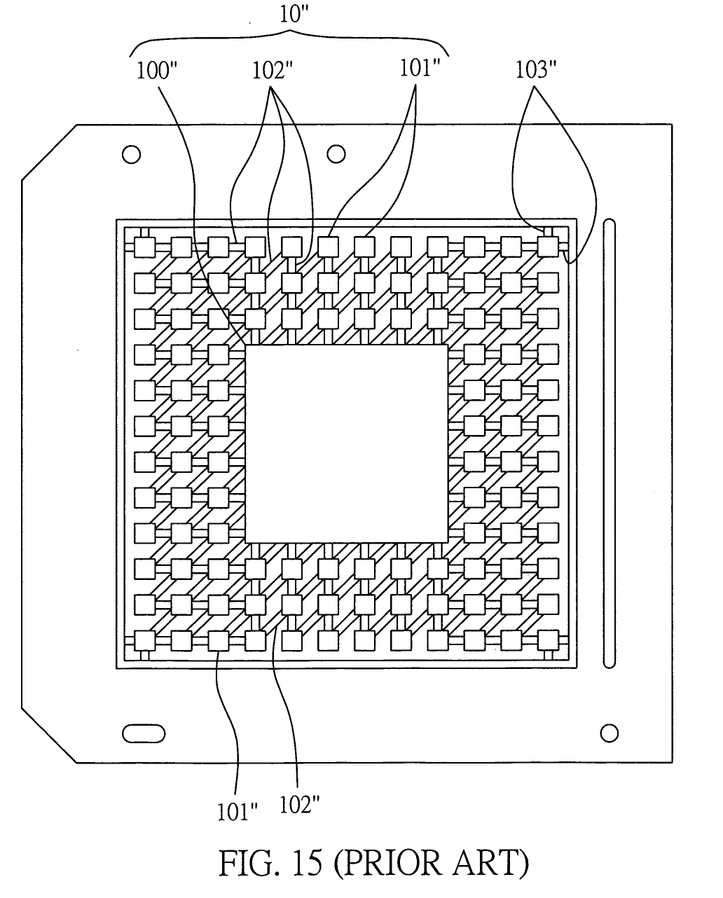

FIG. 11 shows a semiconductor package 7 according to a seventh preferred embodiment of the present invention. This semiconductor package 7 is mostly the same in structure as that of the foregoing fifth preferred embodiment, except that in the semiconductor package 7, a ground ring 716 and a power ring 715 are coaxially formed between the die pad 710 and the leads 711 instead of forming a plurality of conductive members. The ground ring 726 and the power ring 715 provide relatively more flexible electrical connection with a semiconductor chip (not shown) mounted on the die pad 710.

The invention has been described using exemplary preferred embodiments. However, it is to be understood that the scope of the invention is not limited to the disclosed embodiments. On the contrary, it is intended to cover various modifications and similar arrangements. The scope of the claims, therefore, should be accorded the broadest interpretation so as to encompass all such modifications and similar arrangements.

1. A semiconductor package having a high quantity of input/output (I/O) connections, comprising:
a lead frame having a plurality of leads, a die pad having a bottom surface, and at least one conductive member electrically isolated from the die pad so as for the at least one conductive member to be disposed between the leads and the die pad, wherein the at least one conductive member has a bottom surface;
at least one semiconductor chip mounted on the die pad and respectively electrically connected to the leads and the at least one conductive member; and
an encapsulant for encapsulating the semiconductor chip and a portion of the lead frame, allowing a portion of the leads and the bottom surfaces of the at least one conductive member and the die pad to be exposed from the encapsulant.

2. The semiconductor package of claim 1, wherein the at least one conductive member is one selected from the groups consisting of a signal I/O member, a ground ring and a power ring.

3. The semiconductor package of claim 1, wherein a recess is formed between the die pad and the at least one conductive member.

4. The semiconductor package of claim 3, wherein the depth of the recess is the same as the thicknesses of the die pad and the at least one conductive member.

5. The semiconductor package of claim 3, wherein the depth of the recess is smaller than the thicknesses of the die pad and the at least one conductive member.

6. The semiconductor package of claim 1, wherein a downset is formed between the leads and the die pad.

7. The semiconductor package of claim 1, wherein the leads and the die pad are coplanar, allowing bottom surfaces of the leads to be exposed from the encapsulant.

8. The semiconductor package of claim 1, wherein the semiconductor chip is electrically connected to the leads via a plurality of first bonding wires and electrically connected to the at least one conductive member via a plurality of second bonding wires.

9. A lead frame, comprising a plurality of leads, a die pad, and at least one conductive member connected to the die pad via at least one connection portion.

10. The lead frame of claim 9, wherein the at least one conductive member is one selected from the groups consisting of a signal I/O member, a ground ring and a power ring.

11. A method for fabricating a semiconductor package having a high quantity of I/O connections, comprising the steps of:
preparing a lead frame having a plurality of leads, a die pad having a bottom surface, at least one conductive member connected to the die pad and disposed between the leads and the die pad wherein the at least one conductive member having a bottom surface, and at least one connection portion for connecting the at least one conductive member to the die pad;
mounting at least one semiconductor chip on the die pad of the lead frame, and electrically connecting the semiconductor chip respectively to the leads and the at least one conductive member;
forming an encapsulant to encapsulate the semiconductor chip and a portion of the lead frame, allowing the bottom surface of the die pad, the bottom surface of the at least one conductive member, the at least one connection portion, and a portion of the leads to be exposed from the encapsulant; and
removing the at least one connection portion to electrically isolate the at least one conductive member from the die pad, such that the at least one conductive member and the leads serve as I/O connections for electrical connection between the semiconductor chip and external devices.

12. The method of claim 11, wherein the at least one connection portion is removed by using a technique selected from the group consisting of mechanical sawing, laser sawing and grinding.

13. The method of claim 12, wherein after a mechanical sawing or laser sawing technique has been conducted to remove the at least one connection portion, a recess is formed between the at least one conductive member and the die pad.

14. The method of claim 13, wherein when the thickness of the at least one connection portion is the same as that of the die pad, the depth of the recess is the same as the thickness of the die pad.

15. The method of claim 13, wherein when the thickness of the at least one connection portion is smaller than that of the die pad, the depth of the recess is equal to the thickness of the connection portion.

16. The method of claim 15, wherein a stamping or etching process is applied to the lead frame to form a recess on the at least one connection portion so as to make the thickness of the connection portion smaller than that of the die pad.

17. The method of claim 12, wherein the at least one connection portion is formed with a thickness smaller than that of the die pad, such that, subsequent to the grinding process, a portion of the die pad, a portion of the at least one conductive member, a portion of the encapsulant, and/or a portion of the leads are removed, and the connection portion is completely removed to allow the conductive member to be isolated from the die pad.

18. The method of claim 11, wherein a downset is formed between the leads and the die pad.

19. The method of claim 11, wherein the at least one conductive member is one selected from the group consisting of a signal I/O member, a ground ring and a power ring.

20. The method of claim 11, wherein the semiconductor chip is electrically connected to the leads via a plurality of first bonding wires and electrically connected to the at least one conductive member via a plurality of second bonding wires.
